(19) United States
(12) Patent Application Publication
(10) Pub. No.: US 2026/0293262 A1
(43) Pub. Date: Sep. 24, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Hsiao-Chu CHEN, Caotun Township (TW); Wei-Hsuan CHEN, Taoyuan City (TW); Chun-Ting LEE, Hsinchu County (TW); Sheng-Yu WANG, Hsinchu County (TW)

(73) Assignee: Taiwan Semiconductor Manufacturing Company, Ltd., Hsinchu (TW)

(21) Appl. No.: 19/085,180

(22) Filed: Mar. 20, 2025

(51) Int. Cl. H10D 64/23; H10D 30/00; H10D 30/01; H10D 64/62

(52) U.S. Cl. CPC H10D 64/258; H10D 30/0198; H10D 30/501; H10D 64/62

(57) ABSTRACT

Semiconductor structures and methods for manufacturing the same are provided. The semiconductor structure includes a plurality of nanostructures formed over a substrate, and a gate structure formed over the nanostructures. The semiconductor structure includes a mask layer formed on the gate structure, and a source/drain (S/D) structure formed adjacent to the gate structure. The semiconductor structure includes a first dielectric layer formed over the S/D structure, and an S/D contact structure extending through the first dielectric layer, wherein the S/D contact structure is through the dielectric layer. A top surface of the S/D contact structure is aligned with a top surface of the mask layer.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to 3O-1 illustrate cross-sectional representations of various stages of manufacturing the semiconductor structure shown along line A-A′ in FIG. 1E and FIG. 2, in accordance with some embodiments.

FIGS. 3A-2 to 3O-2 illustrate cross-sectional representations of various stages of manufacturing the semiconductor structure shown along line B-B′ in FIG. 1E and FIG. 2, in accordance with some embodiments.

FIG. 4 shows a top-view representation of the semiconductor structure after forming the S/D contact structure and the conductive via, in accordance with some embodiments.

FIG. 5 illustrate a cross-sectional representation of the semiconductor structure 100a along line C-C′ in FIG. 4, in accordance with some embodiments.

FIG. 6 illustrate an enlarged cross-sectional representation of the semiconductor structure in region A of FIG. 4, in accordance with some embodiments.

FIG. 7 illustrate a cross-sectional representation of a semiconductor structure, in accordance with some embodiments.

FIG. 8 illustrate a cross-sectional representation of a semiconductor structure, in accordance with some embodiments.

FIG. 9 illustrate a cross-sectional representation of a semiconductor structure, in accordance with some embodiments.

FIG. 10 illustrate a cross-sectional representation of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a gate structure formed over a substrate and a source/drain (S/D) structure formed adjacent to the gate structure. An S/D contact structure is formed over the S/D structure without passing through an etch stop layer. A mask layer is formed on the gate structure to protect the gate structure. A conductive via is formed on the S/D contact structure, and the conductive via is separated from the gate structure by the mask layer. The mask layer has a high etching selectively with respect to the dielectric layer, and the mask layer is not removed when removing the dielectric layer to form a trench. Since the mask layer is formed on the gate structure, the gate structure is not damaged when the formation process for the conductive via in the dielectric layer. When the gate structure is protected by the mask layer, the leakage between the conducive via and the gate structure is reduced. In addition, since the mask layer is used to protect the gate structure, the dielectric layer can be low-k dielectric layer (the k value of the dielectric layer is lower than the k value of the mask layer), and the unwanted capacitor between the S/D contact structure and the conductive layer above the S/D contact structure) is reduced. In addition, the width of the conductive via is greater than the width of the S/D contact structure, and thus the resistance of the conductive via is reduced. Therefore, the performance of the semiconductor structure is improved. The S/D structures or the S/D region(s) may refer to a source or a drain, individually or collectively dependent upon the context.

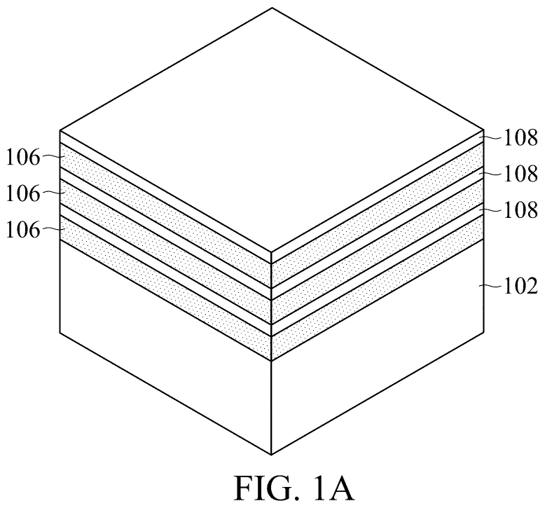

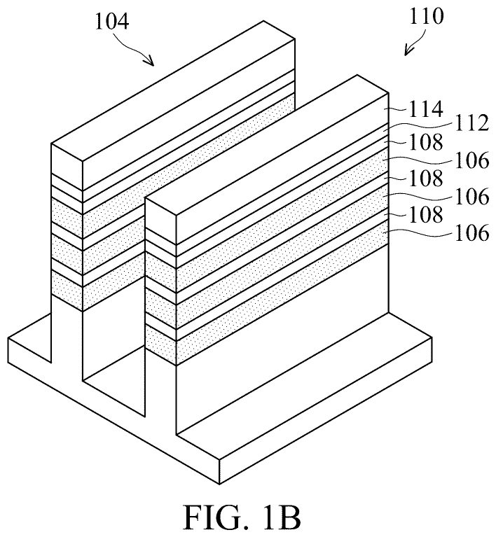

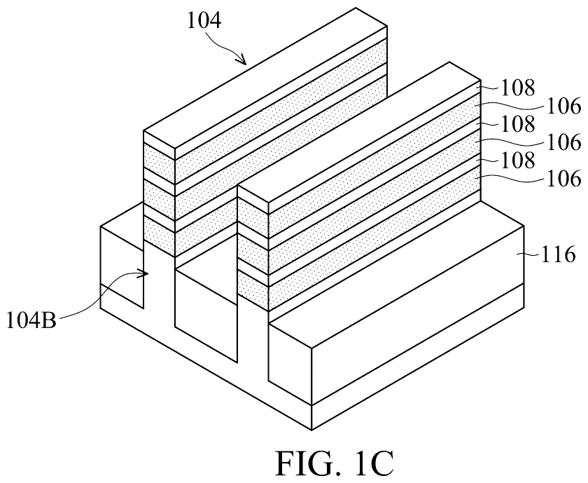

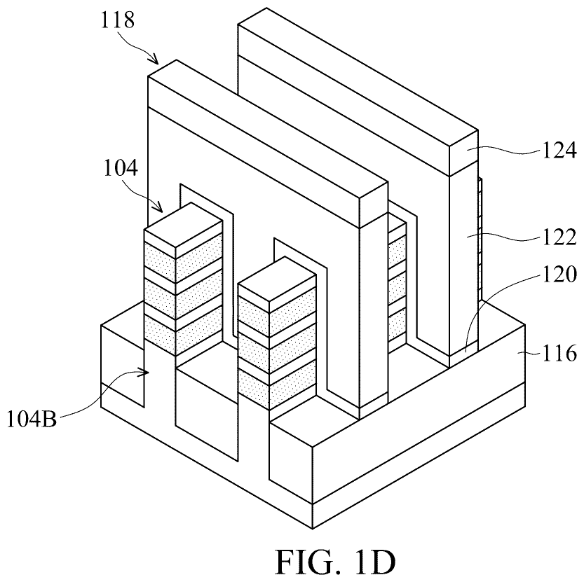

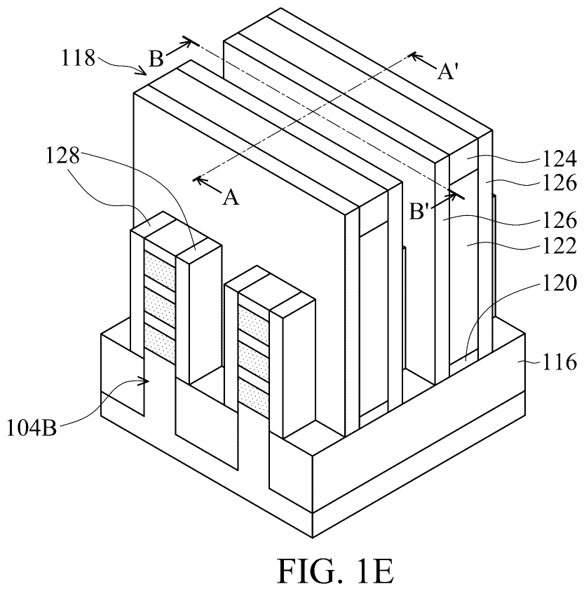

FIGS. 1A to 1E illustrate perspective views of intermediate stages of manufacturing a semiconductor structure 100a in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1B, after the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 104B and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

As shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100 and is also referred to as shallow trench isolation (STI) feature in accordance with some embodiments.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

As shown in FIG. 1D, after the isolation structure 116 is formed, dummy gate structures 118 are formed across the fin structure 104 and extend over the isolation structure 116, in accordance with some embodiments. The dummy gate structures 118 may be used to define the source/drain regions and the channel regions of the resulting

### Semiconductor Structure 100.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

As shown in FIG. 1E, after the dummy gate structures 118 are formed, gate spacers 126 are formed along and covering opposite sidewalls of the dummy gate structure 118 and fin spacers 128 are formed along and covering opposite sidewalls of the source/drain regions of the fin structure 104, in accordance with some embodiments.

The gate spacers 126 may be configured to separate source/drain structures from the dummy gate structure 118 and support the dummy gate structure 118, and the fin spacers 128 may be configured to constrain a lateral growth of subsequently formed source/drain structure and support the fin structure 104.

In some embodiments, the gate spacers 126 and the fin spacers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The formation of the gate spacers 126 and the fin spacers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

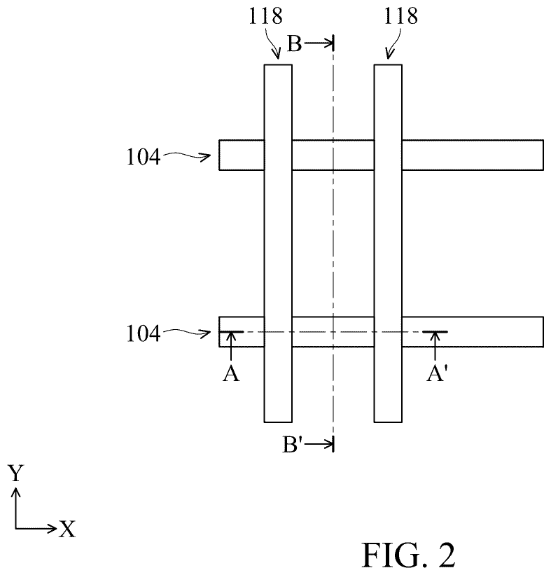

FIG. 2 shows a top-view representation of the semiconductor structure 100a, in accordance with some embodiments.

As shown in FIG. 2, the fin structure 104 is formed along a first direction (e.g. X-axis). The dummy gate structure 118 is formed along a second direction (e.g. Y-axis). The second direction (e.g. Y-axis) is orthogonal to the first direction (e.g. X-axis). The dummy gate structures 118 are formed across the fin structure 104. The S/D structures (formed later) will be formed in the S/D region.

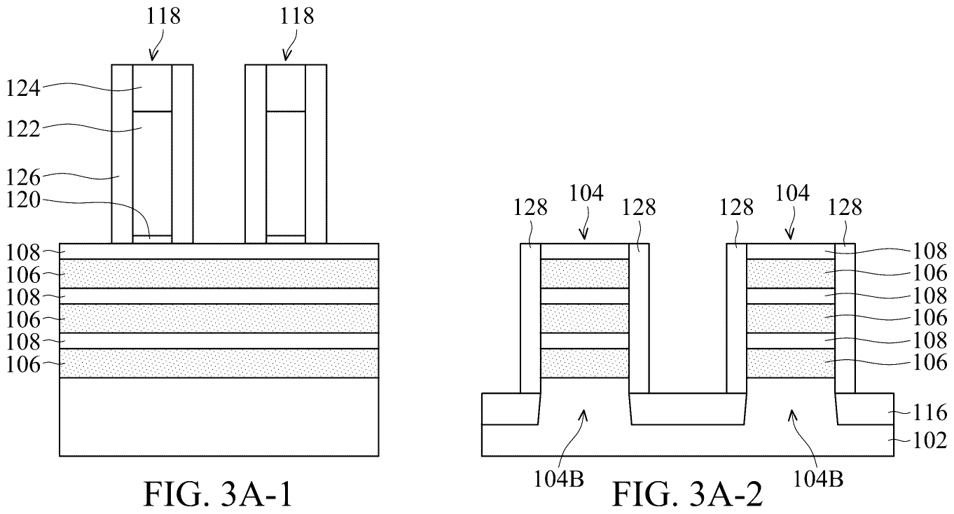

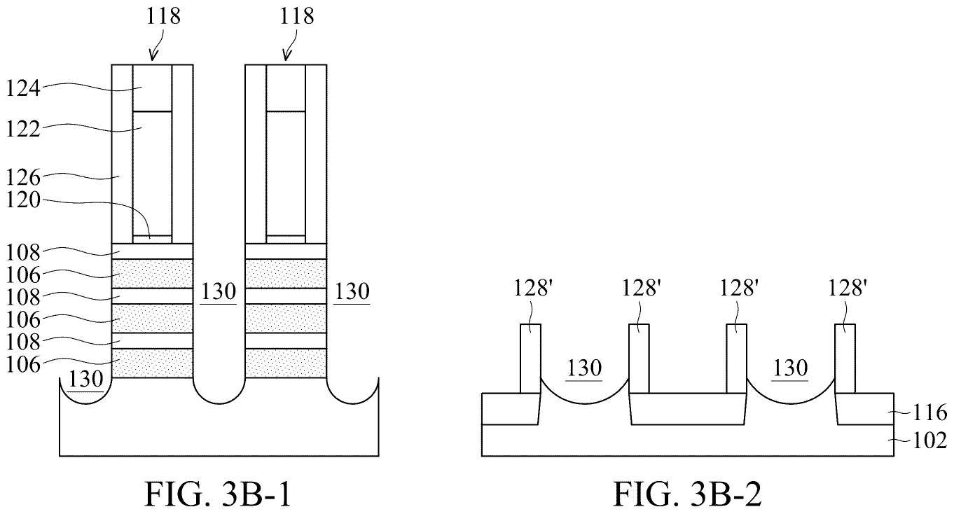

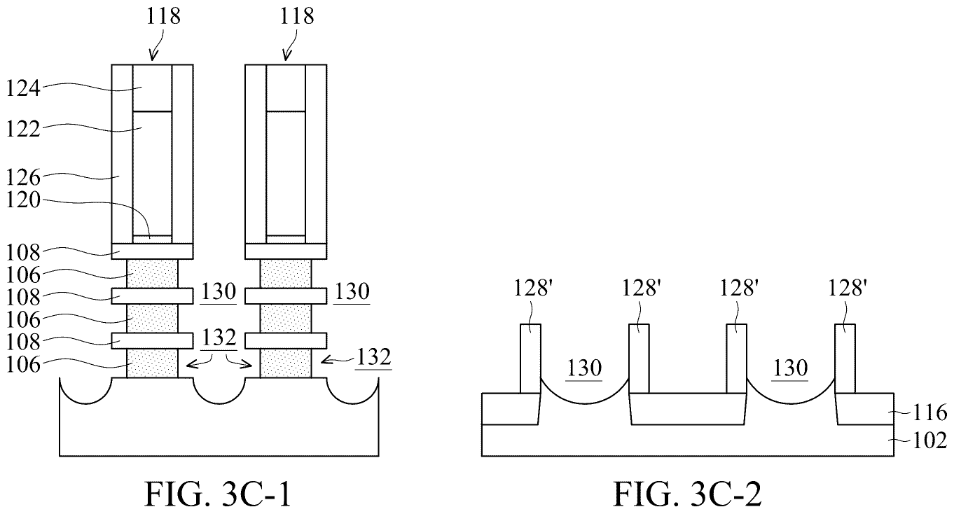

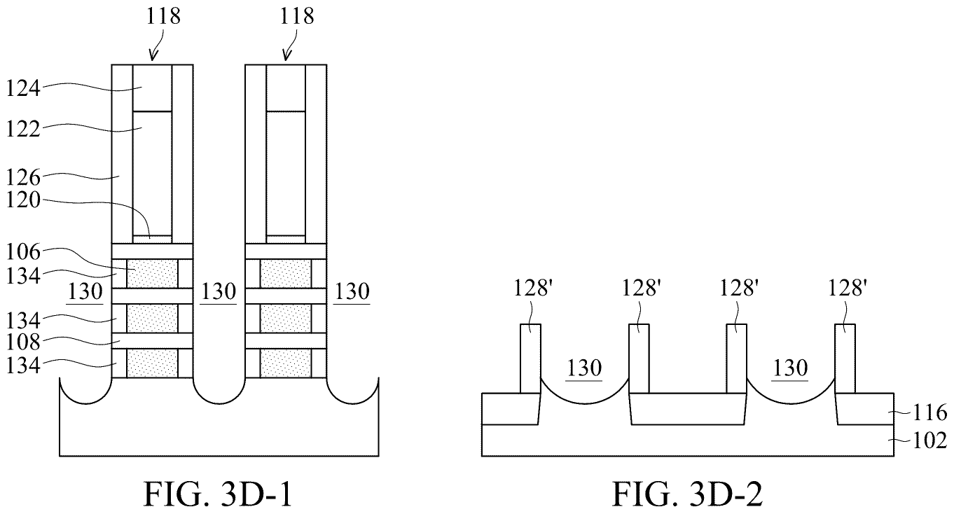

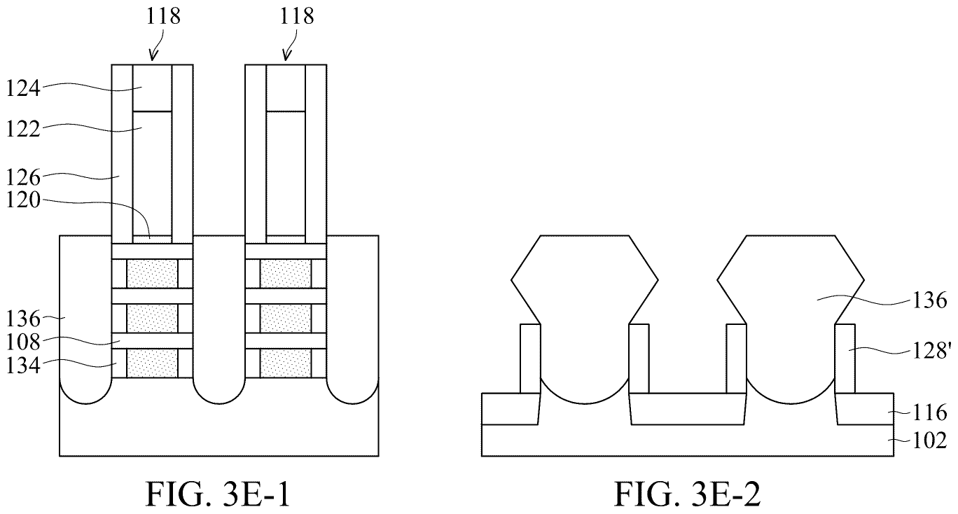

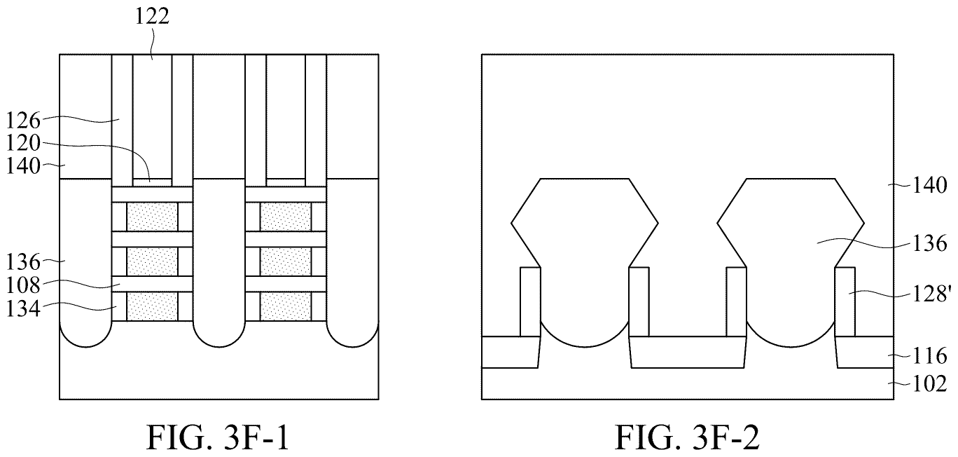

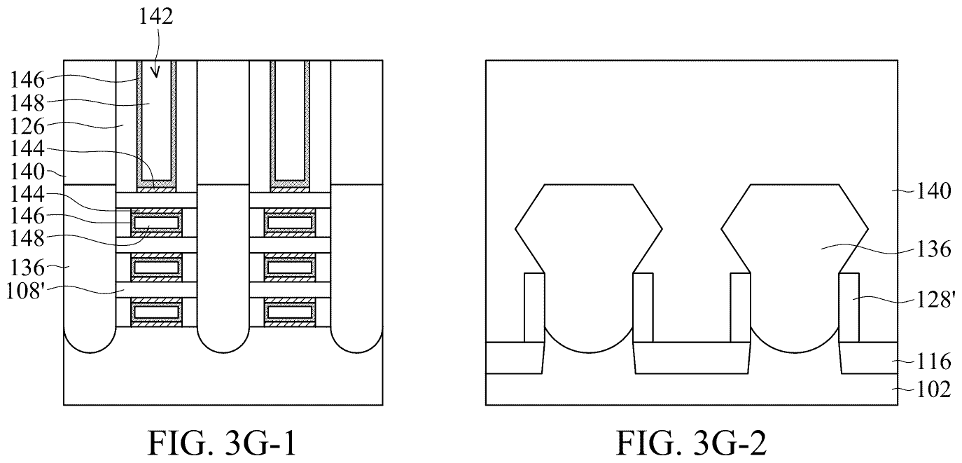

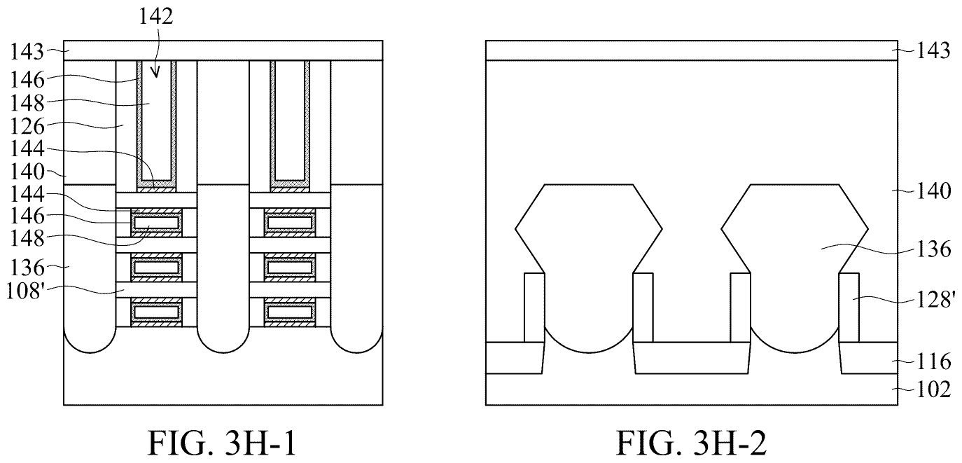

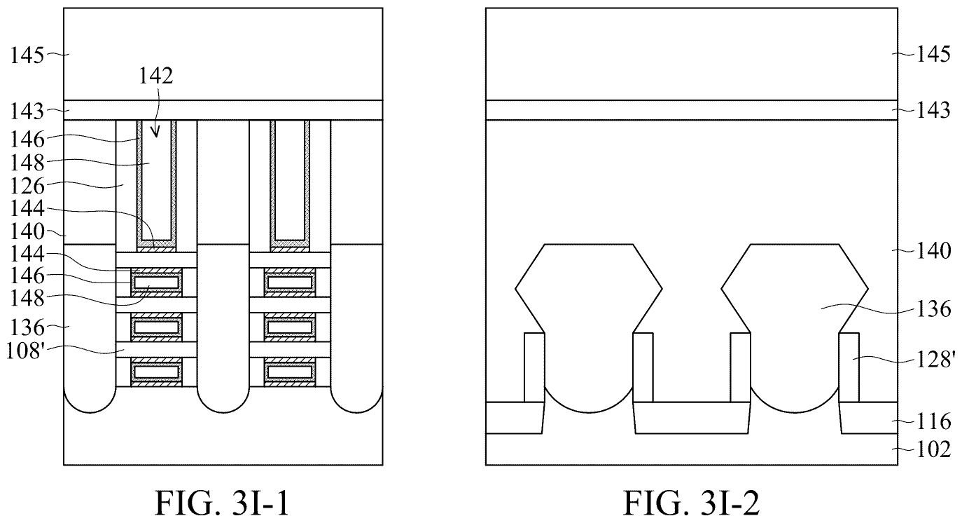

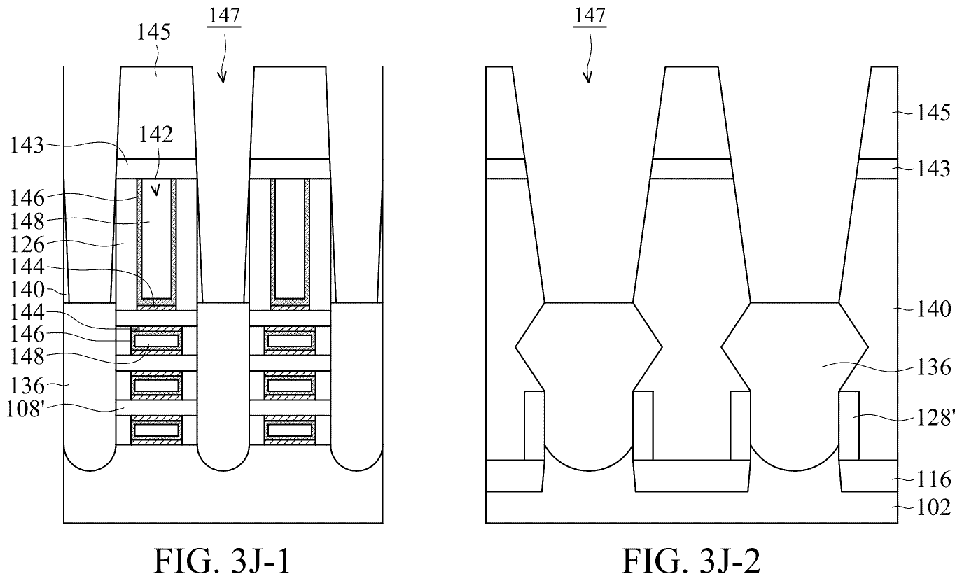

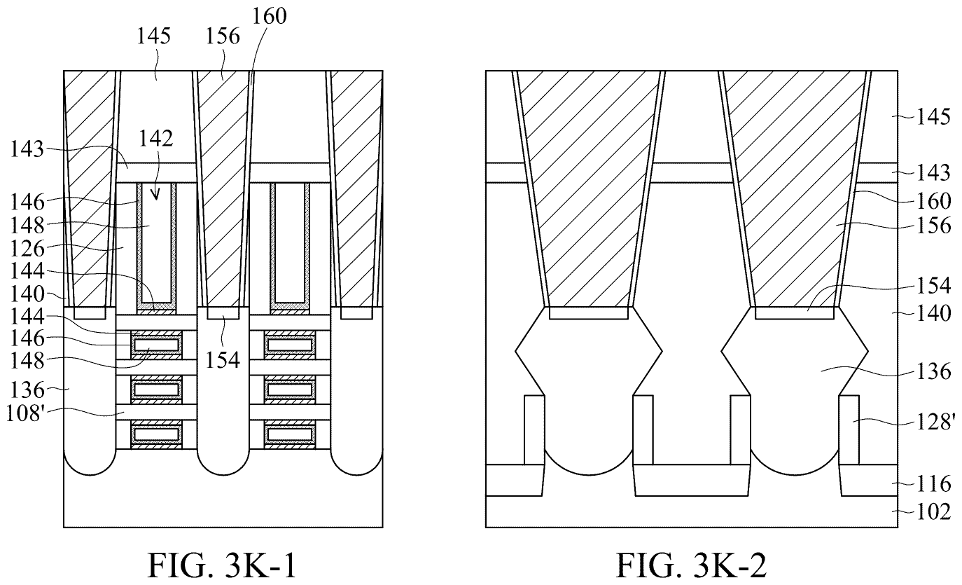

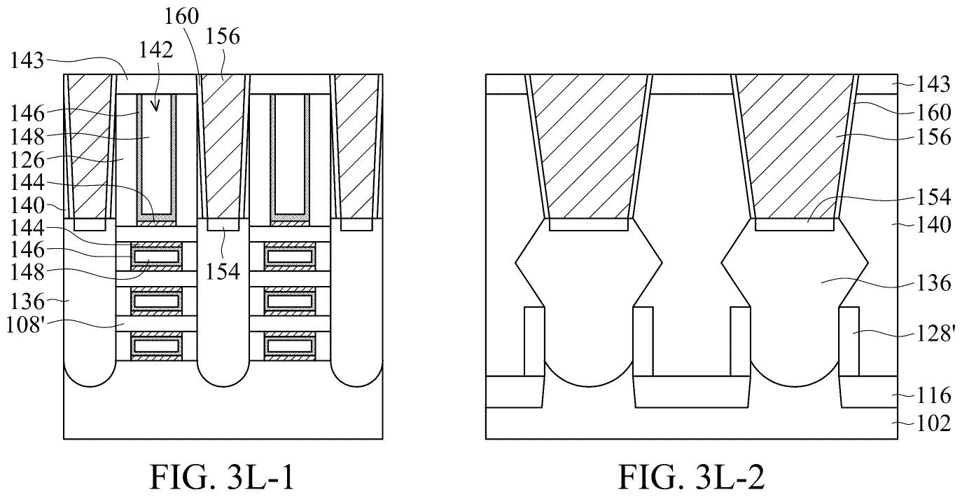

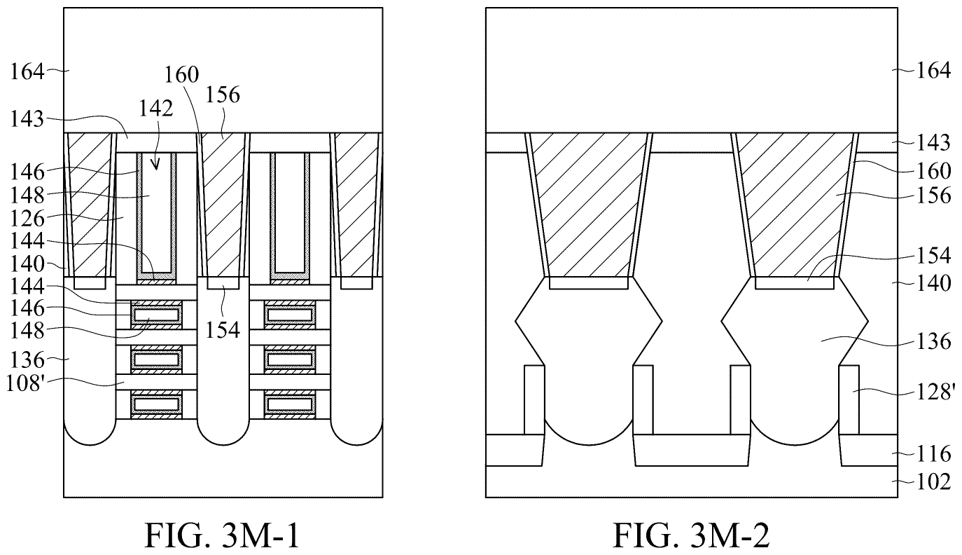

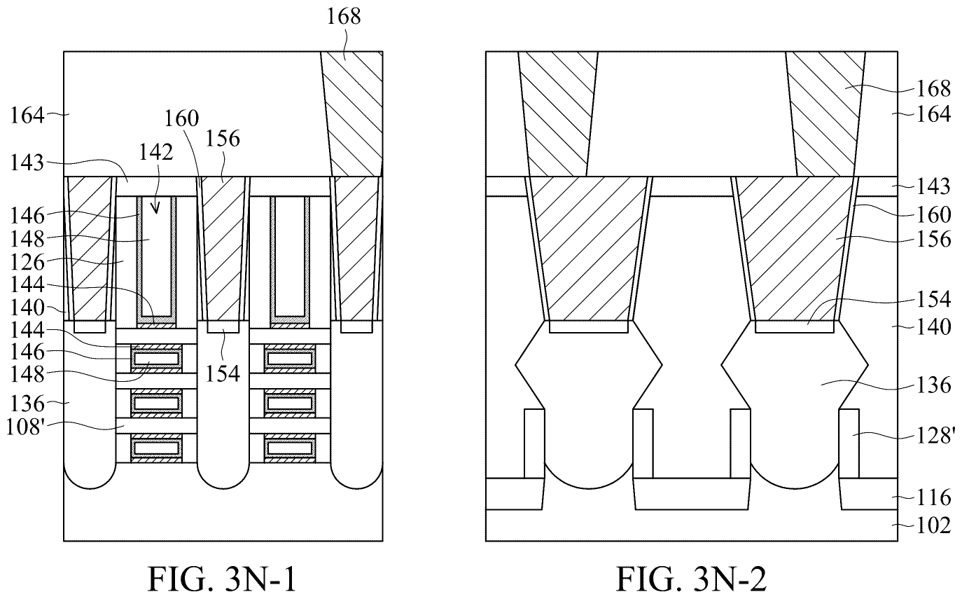

FIGS. 3A-1 to 3O-1 illustrate cross-sectional representations of various stages of manufacturing the semiconductor structure 100a shown along line A-A′ in FIG. 1E and FIG. 2, in accordance with some embodiments. FIGS. 3A-2 to 3O-2 illustrate cross-sectional representations of various stages of manufacturing the semiconductor structure 100 shown along line B-B′ in FIG. 1E and FIG. 2, in accordance with some embodiments.

More specifically, FIG. 3A-1 illustrates the cross-sectional representation shown along line A-A′ in FIG. 1E and FIG. 2, in accordance with some embodiments. FIG. 3A-2 illustrates the cross-sectional representation shown along line B-B′ in FIG. 1E and FIG. 2, in accordance with some embodiments.

As shown in FIGS. 3B-1 and 3B-2, after the gate spacers 126 and the fin spacers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structures 118 and the gate spacers 126 are removed in accordance with some embodiments. In addition, some portions of the base fin structure 104B are also recessed to form curved top surfaces, as shown in FIG. 2B-1 in accordance with some embodiments.

In some embodiments, the fin structure 104 is recessed by performing an etching process. The etching process may be an anisotropic etching process, such as dry plasma etching, and the dummy gate structure 118 and the gate spacers 126 are used as etching masks during the etching process. In some embodiments, the fin spacers 128 are also recessed to form lowered fin spacers 128′.

Afterwards, as shown in FIGS. 3C-1 and 3C-2, after the source/drain (S/D) recesses 130 are formed, the first semiconductor material layers 106 exposed by the source/drain recesses 130 are laterally recessed to form notches 132, in accordance with some embodiments.

In some embodiments, an etching process is performed on the semiconductor structure 100 to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching process such as dry chemical etching, remote plasma etching, wet chemical etching, another suitable technique, or a combination thereof.

Next, as shown in FIGS. 3D-1 and 3D-2, inner spacers 134 are formed in the notches 132 between the second semiconductor material layers 108, in accordance with some embodiments. The inner spacers 134 are configured to separate the source/drain (S/D) structures and the gate structures formed in subsequent manufacturing processes in accordance with some embodiments.

In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Afterwards, as shown in FIGS. 3E-1 and 3E-2, after the inner spacers 134 are formed, source/drain (S/D) structures 136 are formed in the S/D recesses 130, in accordance with some embodiments.

In some embodiments, the S/D structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the S/D structures 136 are made of any applicable material, such as Ge, Si, GaAs, AlGaAs, SiGe, GaAsP, SiP, SiC, SiCP, or a combination thereof.

In some embodiments, the S/D structures 136 are in-situ doped during the epitaxial growth process. For example, the S/D structures 136 may be the epitaxially grown SiGe doped with boron (B). For example, the S/D structures 136 may be the epitaxially grown Si doped with carbon to form silicon: carbon (Si:C) source/drain features, phosphorous to form silicon: phosphor (Si:P) source/drain features, or both carbon and phosphorous to form silicon carbon phosphor (SiCP) source/drain features. In some embodiments, the S/D structures 136 are doped in one or more implantation processes after the epitaxial growth process.

Next, as shown in FIGS. 3F-1 and 3F-2, after the S/D structures 136 are formed, an interlayer dielectric (ILD) layer 140 is conformally formed to cover the S/D structures 136, in accordance with some embodiments. It should be noted that no contact etch stop layer is formed between the S/D structures 136 and the ILD layer 140.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the ILD layer 140 are deposited, a planarization process such as CMP (chemical mechanical planarization) process or an etch-back process may be performed until the gate electrode layers 120 of the dummy gate structures 118 are exposed, as shown in FIG. 3F-1 in accordance with some embodiments.

Afterwards, as shown in FIGS. 3G-1 and 3G-2, the dummy gate structures 118 are replaced by a gate structure 142, in accordance with some embodiments. More specifically, the dummy gate structures 118 and the first semiconductor material layers 106 are removed to form nanostructures 108′ (channel layers) with the second semiconductor material layers 108, in accordance with some embodiments. The S/D structure 136 is attached to the nanostructures 108′ (channel layers).

The removal process may include one or more etching processes. For example, when the dummy gate electrode layers 122 are polysilicon, a wet etchant such as a tetramethylammonium hydroxide (TMAH) solution may be used to selectively remove the dummy gate electrode layers 122. Afterwards, the dummy gate dielectric layers 120 may be removed using a plasma dry etching, a dry chemical etching, and/or a wet etching. The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions. In some embodiments, the upper portions of the gate spacers 126 are also removed.

After the nanostructures 108′ (channel layers) are formed, the gate structures 142 are formed wrapping around the nanostructures 108′. The gate structures 142 wrap around the nanostructures 108′ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layers 144 are oxide layers formed around the nanostructures 108′ and on the top of the base fin structure 104B. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacers 126 and the inner spacers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layers 148 are formed on the gate dielectric layer 146. In some embodiments, the gate electrode layers 148 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 148 are formed using chemical vapor deposition (CVD), atomic layer deposition (ALD), electroplating, another applicable method, or a combination thereof. Other conductive layers, such as work function metal layers, may also be formed in the gate structures 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layers 148 are formed, a planarization process such as CMP or an etch-back process may be performed until the ILD layer 140 is exposed.

Afterwards, as shown in FIGS. 3H-1 and 3H-2, a mask layer 143 is formed on the ILD layer 140 and the gate structure 142, in accordance with some embodiments. The mask layer 143 is used as protection layer to protect the gate structure 142 from being damaged by the following process.

In some embodiments, the mask layer 143 is made of silicon nitride (SiN), silicon carbide (SiC), silicon oxynitride (SiON), silicon carbon nitride (SiCN), silicon oxycarbide (SiOC), silicon oxide carbonitride (SiOCN), or a combination thereof. In some embodiments, the mask layer 143 is formed by chemical vapor deposition (CVD), atomic layer deposition (ALD), electroplating, or another applicable method.

Next, as shown in FIGS. 3I-1 and 3I-2, a dielectric layer 145 is formed on the mask layer 143, in accordance with some embodiments.

In some embodiments, the dielectric layer 145 is made of silicon oxide, silicon nitride, silicon oxynitride, phosphosilicate glass (PSG), borophosphosilicate glass (BPSG), and/or other applicable low-k dielectric materials. The dielectric layer 145 may be formed by chemical vapor deposition (CVD), physical vapor deposition, (PVD), atomic layer deposition (ALD), or other applicable processes.

Afterwards, as shown in FIGS. 3J-1 and 3J-2, a trench 147 is formed through the dielectric layer 145, the mask layer 143 and the ILD layer 140 to expose the S/D structure 136, in accordance with some embodiments.

The trench 147 may be formed using a photolithography process and an etching process. In addition, some portions of the S/D structures 136 exposed by the trench 147 may also be etched during the etching process.

Next, as shown in FIGS. 3K-1 and 3K-2, a metal silicide layer 154 and an S/D contact structure 156 are formed in the trench 147, in accordance with some embodiments. The trench 147 is not filled with the S/D contact structure 156. Next, a dielectric layer 160 is formed in the trench 147 to surround the S/D contact structure 156.

After the trench 147 is formed, the metal silicide layers 154 may be formed by forming a metal layer over the top surface of the S/D structures 136 and annealing the metal layer so the metal layer reacts with the S/D structures 136 to form the metal silicide layers 154. The unreacted metal layer may be removed after the metal silicide layers 154 are formed. In some embodiments, the metal silicide layer 154 has a curved profile. In some embodiments, the metal silicide layer 154 has a non-flat top surface and a non-flat bottom surface. The non-flat interface is between the metal silicide layer 154 and S/D structures 136. The non-flat interface is between the metal silicide layer 154 and S/D contact structure 156.

In some embodiments, the S/D contact structure 156 is made of a conductive material including tungsten (W), molybdenum (Mo), aluminum (Al), copper (Cu), titanium (Ti), cobalt, ruthenium (Ru), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the S/D contact structure 156 is formed using chemical vapor deposition (CVD), atomic layer deposition (ALD), electroplating, another applicable method, or a combination thereof.

In some embodiments, a barrier layer (not shown) is formed to surround the S/D contact structure 156. In some embodiments, the barrier layer is made of tantalum nitride, although other materials, such as tantalum, titanium, titanium nitride, or the like, may also be used. In some embodiments, the barrier layer (not shown) is formed using chemical vapor deposition (CVD), atomic layer deposition (ALD), electroplating, another applicable method, or a combination thereof.

In some embodiments, the an interposing layer, such as dielectric layer 160, which may include multilayers made of multiple dielectric materials, such as silicon oxide, silicon nitride (SiN), silicon carbide (SiC), silicon oxynitride (SiON), silicon carbon nitride (SiCN), silicon oxide carbonitride (SiOCN), silicon oxynitride, phosphosilicate glass (PSG), borophosphosilicate glass (BPSG), and/or other applicable low-k dielectric materials. The dielectric layer 160 may be formed by chemical vapor deposition (CVD), physical vapor deposition, (PVD), atomic layer deposition (ALD), or other applicable processes.

Afterwards, as shown in FIGS. 3L-1 and 3L-2, the dielectric layer 145, a portion of the S/D contact structure 156 and a portion of the dielectric layer 160 are removed by a planarization process to expose the mask layer 143, in accordance with some embodiments. In some embodiments, the planarization process is a CMP process. The mask layer 143 is used as a stop layer. As a result, the top surface of the S/D contact structure 156 is substantially leveled with the top surface of the mask layer 143. In addition, the top surface of the S/D contact structure 156 is substantially leveled with the top surface of the dielectric layer 160.

Next, as shown in FIGS. 3M-1 and 3M-2, a dielectric layer 164 is formed on the S/D contact structure 156, the dielectric layer 160 and the mask layer 143, in accordance with some embodiments.

It should be noted that the dielectric layer 164 and the mask layer 143 are made of different material. The mask layer 143 has a high etching selectivity with respect to the dielectric layer 164. The mask layer 143 is not removed while the dielectric layer 164 is removed. The dielectric constant (K value) of the mask layer 143 is greater than the dielectric constant (K value) of the dielectric layer 164. The mask layer 143 can be used as a protection layer to protect the gate structure 142 from being etched or damaged. In addition, the dielectric constant (K value) of the mask layer 143 is greater than the dielectric constant (K value) of the dielectric layer 160.

The dielectric layer 164 may include multilayers made of multiple dielectric materials, such as silicon oxide, silicon nitride, SiOC, silicon oxynitride, phosphosilicate glass (PSG), borophosphosilicate glass (BPSG), and/or other applicable low-k dielectric materials. The dielectric layer 164 may be formed by chemical vapor deposition (CVD), physical vapor deposition, (PVD), atomic layer deposition (ALD), or other applicable processes.

Afterwards, as shown in FIGS. 3N-1 and 3N-2, a conductive via 168 is formed on the S/D contact structure 156, in accordance with some embodiments. The conducive via 168 is electrically connected to the S/D structure 136 by the S/D contact structure 156.

The conductive via 168 is formed by forming a trench through the dielectric layer 164, and then a conducive material is formed in the trench. The conductive via 168 is formed through the dielectric layer 164 without passing through an etch stop layer. In other words, the sidewall surface of the conductive via 168 is in contact with the dielectric layer 164, and not contact with an etch stop layer. The interface between the conducive via 168 and the S/D contact structure 156 is aligned with the top surface of the mask layer 143. In some embodiments, the conductive via 168 extends into the S/D contact structure 156. As a result, the bottommost surface of the conductive via 168 is lower than the topmost surface of the S/D contact structure 156.

Note that since the mask layer 143 has a high etching selectivity with respect to the dielectric layer 164, the mask layer 143 is not removed when a portion of the dielectric layer 164 is removed. Therefore, the gate structure 142 is protected by the mask layer 143 during the formation process of the conductive via 168.

It should be noted that the conductive via 168 is through a single layer, not two layers. The conductive via 168 is through a single dielectric layer 164 made of uniform one material with single dielectric constant. The conductive via 168 is not through two layers with different materials. The conductive via 168 is not through an interface between two different materials. In some embodiments, the conductive via 168 is not through an etch stop layer (e.g. SiN). The top surface of the conductive via 168 is interfacing the conductive layer 176, and the bottom surface of the conductive via 168 is interfacing the S/D contact structure 156. The top surface of the conductive via 168 is in contact with or in direct contact with the conductive layer 176, and the bottom surface of the conductive via 168 is in contact with or in direct contact with the S/D contact structure 156. The sidewall surface of the conductive via 168 is interfacing the dielectric layer 164. The conductive via 168 has a top portion and a bottom portion, and the sidewall surface of the top portion of the conductive via 168 and the sidewall surface of the bottom portion of the conductive via 168 are interfacing the same materials (e.g. the dielectric layer 164).

In some embodiments, the conductive via 168 is made of tungsten (W), ruthenium (Ru), molybdenum (Mo), or the like. In some embodiments, the conductive via 168 is formed by performing a deposition process, such as chemical vapor deposition (CVD), physical vapor deposition, (PVD), atomic layer deposition (ALD), or other applicable processes.

In some embodiments, a barrier layer (not shown) is formed in the trench before forming the conductive material. In some embodiments, the barrier layer (not shown) is made of titanium (Ti), titanium nitride (TiN), tantalum (Ta), tantalum nitride (TaN), or another applicable material. In some embodiments, the barrier layer (not shown) is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

Next, as shown in FIG. 3O-1 and 3O-2, a conductive layer 176 is formed on the conductive via 168 and the dielectric layer 164, in accordance with some embodiments. The conductive via 168 is electrically connected to the conductive layer 176. The S/D structure 136 is electrically connected to the conductive layer 176 by the S/D contact structure 156 and the conductive via 168. A portion of the conductive via 168 is formed on the top surface of the mask layer 143. The bottom surface of the conductive via 168 faces and in contact with the top surface of the mask layer 143.

It should be noted that the conductive via 168 is through a single layer, not two layers. The conductive via 168 is through a single dielectric layer 164 made of one material. The conductive via 168 is not through two layers with different materials and with two different dielectric constants. In some embodiments, the conductive via 168 is not through the etch stop layer (e.g. SiN).

The top surface of the conductive via 168 is interfacing the conductive layer 176, and the bottom surface of the conductive via 168 is interfacing the S/D contact structure 156. The top surface of the conductive via 168 is in contact with the conductive layer 176, and the bottom surface of the conductive via 168 is in contact with the S/D contact structure 156. The sidewall surface of the conductive via 168 is interfacing the dielectric layer 164. The conductive via 168 has a top portion and a bottom portion, and the sidewall surface of the top portion of the conductive via 168 and the sidewall surface of the bottom portion of the conductive via 168 are interfacing the same materials (e.g. the dielectric layer 164).

The top surface of the S/D contact structure 156 is substantially aligned with the top surface of the mask layer 143. The top surface of the S/D contact structure 156 is substantially leveled with the top surface of the mask layer 143. The S/D contact structure 156 is surrounded by the dielectric layer 160. The electrical conductivity of the metal silicide layer 154 is between the electrical conductivity of the S/D structure 136 and the electrical conductivity of the S/D contact structure 156. The electrical conductivity of the S/D contact structure 156 is greater than the electrical conductivity of the S/D structure 136.

The sidewall surface of the inner spacer layer 134 is substantially aligned with the sidewall surface of the mask layer 143. In addition, the sidewall surface of the gate spacer layer 126 is substantially aligned with the sidewall surface of the mask layer 143. Note that the mask layer 143 is not formed on the S/D contact structure 156, nor is it formed on the dielectric layer 160.

The dielectric constant of the dielectric layer 160 is greater than the dielectric constant of the gate spacer layer 126. The dielectric constant of the mask layer 143 is greater than or equal to the dielectric constant of the dielectric layer 160. The dielectric constant of the mask layer 143 is greater than or equal to the dielectric constant of the gate spacer layer 126.

Since the mask layer 143 has a high etching selectivity with respect to the dielectric layer 164. The mask layer 143 is not removed while the dielectric layer 164 is removed. The mask layer 143 can be used as a protection layer to protect the gate structure 142 from being etched or damaged. When the gate structure 142 is protected by the mask layer 143, the leakage between the conducive via 168 and the gate structure 142 is reduced.

Furthermore, since the mask layer 143 is used to protect the gate structure 142, the dielectric layer 164 can be low-k dielectric layer (the k value of the dielectric layer 164 is lower than the k value of the mask layer 143), and the unwanted capacitor between the S/D contact structure 156 and the conductive layer 176 is reduced.

In addition, since the mask layer 143 is between the gate structure 142 and the S/D contact structure 156, the conducive via 168 is separated from the gate structure 142 by the mask layer 143. The risk of the leakage between the conducive via 168 and the gate structure 142 is greatly reduced. The width of the conductive via 168 is greater than the width of the S/D contact structure 156, and thus the resistance of the conductive via 168 is reduced. Therefore, the performance of the semiconductor structure 100a is improved.

In some embodiments, the conductive layer 176 is made of tungsten (W), ruthenium (Ru), molybdenum (Mo), copper (Cu) or another applicable material. In some embodiments, the conductive layer 176 is formed by performing a deposition process, such as chemical vapor deposition (CVD), physical vapor deposition, (PVD), atomic layer deposition (ALD), or other applicable processes.

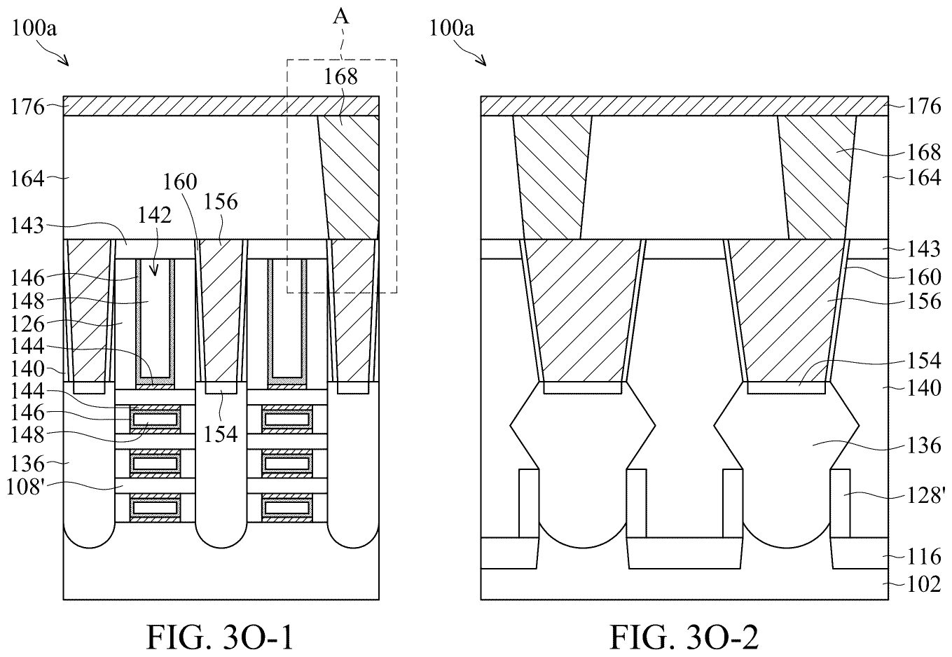

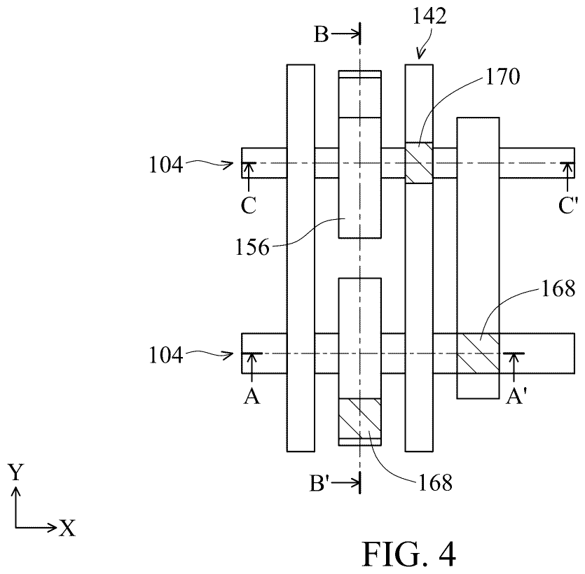

FIG. 4 shows a top-view representation of the semiconductor structure 100a after forming the S/D contact structure 156 and the conductive via 168, in accordance with some embodiments.

The S/D contact structure 156 is formed on the S/D structure 136. The longitude of the S/D contact structure 156 is along the second direction (e.g. y-direction). The longitude of the S/D contact structure 156 is parallel to the longitude of the gate structure 142. The conducive via 168 is formed on the S/D contact structure 156. The conducive via 168 is electrically connected to the S/D structure 136 by the S/D contact structure 156.

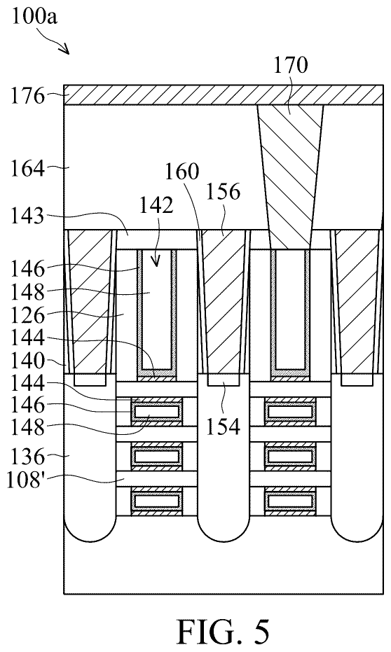

FIG. 5 illustrate a cross-sectional representation of the semiconductor structure 100a along line C-C′ in FIG. 4, in accordance with some embodiments.

As shown in FIG. 5, a gate contact structure 170 is formed on the gate 142, in accordance with some embodiments. The gate contact structure 170 is formed through the dielectric layer 164 and the mask layer 143. The gate contact structure 170 is electrically connected to the gate structure 142. The conducive layer 176 is formed on the gate contact structure 170. The conductive layer 176 extends over the S/D contact structure 156 and the gate contact structure 170. The gate structure 142 is electrically connected to the conducive layer 176 by the gate contact structure 170.

In some embodiments, the gate contact structure 170 is formed by forming a trench through the dielectric layer 164 and the mask layer 143, and then forming a conductive material in the trench. In some embodiments, the gate contact structure 170 is made of tungsten (W), ruthenium (Ru), molybdenum (Mo), copper (Cu) or another applicable material. In some embodiments, the gate contact structure 170 is formed by performing a deposition process, such as chemical vapor deposition (CVD), physical vapor deposition, (PVD), atomic layer deposition (ALD), or other applicable processes.

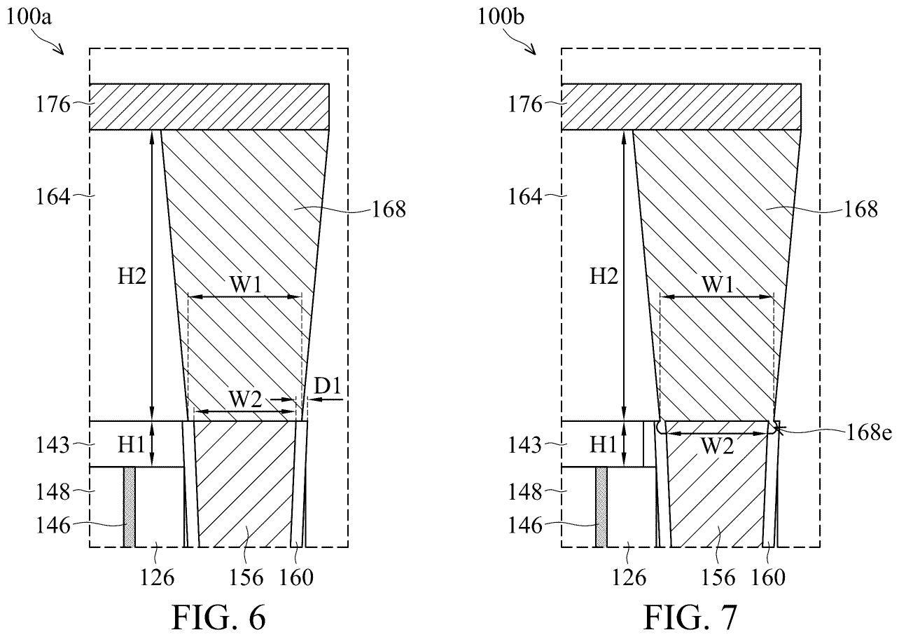

FIG. 6 illustrate an enlarged cross-sectional representation of the semiconductor structure 100a in region A of FIG. 3O-1, in accordance with some embodiments.

As shown in FIG. 6, there is a first height H₁ between the top surface of the S/D contact structure 156 and the top surface of the gate structure 142. In some embodiments, the first height H₁ is in a range from about 2 nm to about 6 nm. The mask layer 143 has the first height H₁.

There is a second height H₂ between the top surface of the conducive via 168 and the top surface of the mask layer 143. The dielectric layer 164 has the second height H₂. In some embodiments, the second height H₂ is in a range from about 10 nm to about 30 nm.

The width of the conducive via 168 is greater than the width of the S/D contact structure 156 along the first direction (e.g. X-axis). In some embodiments, the bottom surface of the conducive via 168 has a first width W₁ along the first direction (e.g. X-axis). In some embodiments, the top surface of the S/D contact structure 156 has a second width W₂ along the first direction (e.g. X-axis). In some embodiments, the first width W₁ is greater than the second width W₂. In some embodiments, there is a difference D₁ between the first width W₁ of the bottom surface of the conducive via 168 and the second width W₂ of the top surface of the S/D contact structure 156 along the first direction (e.g. X-axis). In some embodiments, the difference D₁ is about 1 nm to about 4 nm. The bottom surface of the conducive via 168 is interfacing the top surface of the S/D contact structure 156 and the top surface of the dielectric layer 160. In some other embodiments, the bottom surface of the conducive via 168 is interfacing the top surface of mask layer 143. In other words, the bottom surface of the conducive via 168 is in contact with the top surface of mask layer 143. The gate spacer layer 126 is separated from the conducive via 168 by the mask layer 143. The gate structure 142 is separated from the conducive via 168 by the mask layer 143. The gate electrode layer 148 of the gate structure 142 is separated from the conducive via 168 by the mask layer 143. The unwanted leakage between the gate electrode layer 148 of the gate structure 142 and the conductive via 168 is prevented by the mask layer 143. Therefore, the performance of the semiconductor structure 100a is improved.

FIG. 7 illustrate a cross-sectional representation of a semiconductor structure 100b, in accordance with some embodiments.

The semiconductor structure 100b of FIG. 7 includes elements that are similar to, or the same as, elements of the semiconductor structure 100a of FIG. 3O-1, the difference between the FIG. 7 and FIG. 3O-1 is that the conductive via 168 has an extending portion 168e formed on a sidewall surface of the S/D contact structure 156. The extending portion 168e of the conductive via 168 covers the sidewall surface of the S/D contact structure 156. The extending portion 168e of the conductive via 168 is separated from the mask layer 143 by the dielectric layer 160.

The bottom surface of the extending portion 168e of the conductive via 168 is lower than the top surface of the mask layer 143. The bottom surface of the extending portion 168e of the conductive via 168 is lower than the bottom surface of the dielectric layer 164. The gate electrode layer 148 of the gate structure 142 is separated from the conducive via 168 by the mask layer 143. The unwanted leakage between the gate electrode layer 148 of the gate structure 142 and the conductive via 168 is prevented by the mask layer 143. Therefore, the performance of the semiconductor structure 100b is improved.

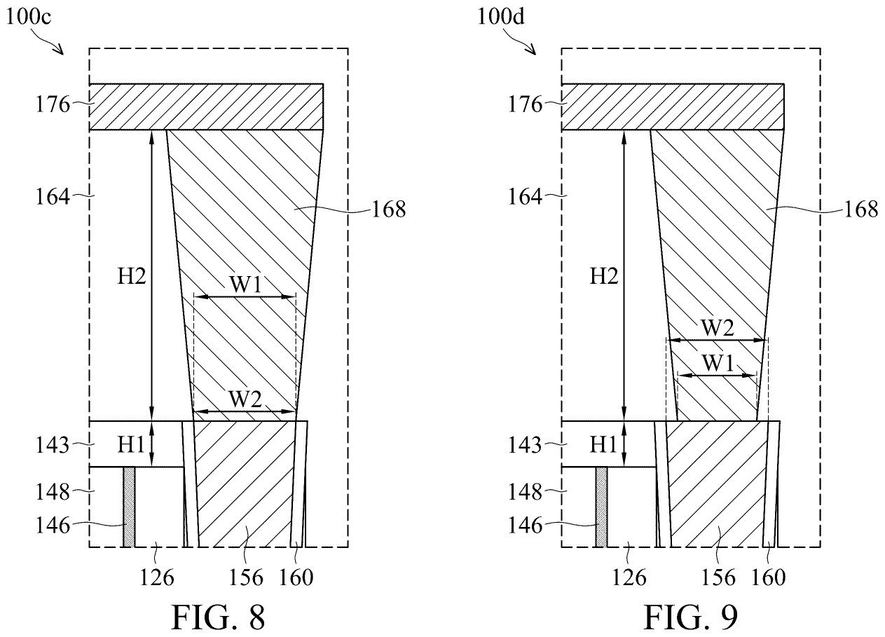

FIG. 8 illustrate a cross-sectional representation of a semiconductor structure 100c, in accordance with some embodiments.

The semiconductor structure 100c of FIG. 8 includes elements that are similar to, or the same as, elements of the semiconductor structure 100a of FIG. 3O-1, the difference between the FIG. 8 and FIG. 3O-1 is that the first width W₁ f the bottom surface of the conducive via 168 is substantially equal to the second width W₂ of the top surface of the S/D contact structure 156 along the first direction (e.g. X-axis).

FIG. 9 illustrate a cross-sectional representation of a semiconductor structure 100d, in accordance with some embodiments.

The semiconductor structure 100d of FIG. 9 includes elements that are similar to, or the same as, elements of the semiconductor structure 100a of FIG. 3O-1, the difference between the FIG. 9 and FIG. 3O-1 is that the first width W₁ f the bottom surface of the conducive via 168 is smaller than the second width W₂ of the top surface of the S/D contact structure 156 along the first direction (e.g. X-axis).

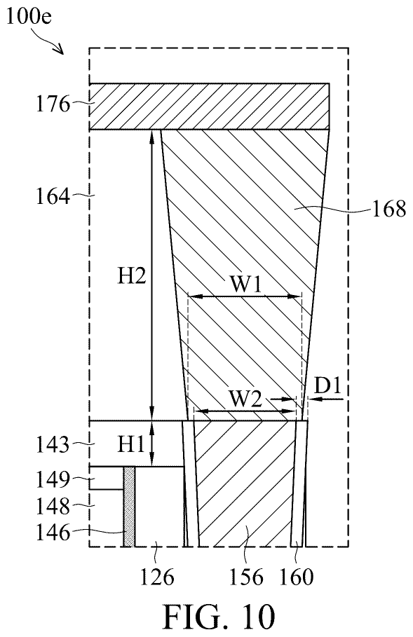

FIG. 10 illustrate a cross-sectional representation of a semiconductor structure 100e, in accordance with some embodiments.

The semiconductor structure 100e of FIG. 10 includes elements that are similar to, or the same as, elements of the semiconductor structure 100a of FIG. 3O-1, the difference between the FIG. 10 and FIG. 3O-1 is that a cap layer 149 is formed on the gate structure 142.

In some embodiments, the cap layer 149 is a conductive cap layer 149. The cap layer 149 is made of made of conducive material, such as tungsten (W), ruthenium (Ru), molybdenum (Mo), copper (Cu) or another applicable material. In some embodiments, the cap layer 149 is formed by performing a deposition process, such as chemical vapor deposition (CVD), physical vapor deposition, (PVD), atomic layer deposition (ALD), or other applicable processes.

In some embodiments, the cap layer 149 is formed by performing a bottom-up deposition process. The bottom-up deposition process generally refers to a deposition process that fills an opening from bottom to top. In some embodiments, the bottom-up deposition process is a selective CVD process that the cap layer 149 is selectively deposited on the gate structure 142.

It should be appreciated that the semiconductor structures 100a to 100e having the conducive via 168 is separated from the gate structure 142 by the mask layer 143 described above may also be applied to FinFET structures, CFET (complementary field-effect transistor), or forksheet, similar to that shown in FIGS. 1 and 10, although not shown in the figures.

It should be noted that same elements in FIGS. 1A to 10 may be designated by the same numerals and may include similar or the same materials and may be formed by similar or the same processes; therefore such redundant details are omitted in the interest of brevity. In addition, although FIGS. 1A to 10 are described in relation to the method, it will be appreciated that the structures disclosed in FIGS. 1A to 10 are not limited to the method but may stand alone as structures independent of the method. Similarly, although the methods shown in FIGS. 1A to 10 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes forming a gate structure, a source/drain (S/D) structure adjacent to the gate structure. An S/D contact structure is formed over the S/D structure without passing through an etch stop layer. A mask layer is formed on the gate structure to protect the gate structure. A conductive via is formed on the S/D contact structure, and the conductive via is separated from the gate structure by the mask layer. The mask layer has a high etching selectively with respect to the dielectric layer, and the mask layer is not removed when removing the dielectric layer to form a trench. Since the mask layer is formed on the gate structure, the gate structure is not damaged when the formation process for the conductive via in the dielectric layer. When the gate structure is protected by the mask layer, the leakage between the conducive via and the gate structure is reduced.

In addition, since the mask layer is used to protect the gate structure, the dielectric layer can be low-k dielectric layer (the k value of the dielectric layer is lower than the k value of the mask layer), and the unwanted capacitor between the S/D contact structure and the conductive layer above the S/D contact structure) is reduced. Furthermore, the width of the conductive via is greater than the width of the S/D contact structure, and thus the resistance of the conductive via is reduced. Therefore, the performance of the semiconductor structure is improved.

In some embodiments, a semiconductor structure is provided. The semiconductor structure includes a plurality of nanostructures formed over a substrate, and a gate structure formed over the nanostructures. The semiconductor structure includes a mask layer formed on the gate structure, and a source/drain (S/D) structure formed adjacent to the gate structure. The semiconductor structure includes a first dielectric layer formed over the S/D structure, and an S/D contact structure extending through the first dielectric layer, wherein the S/D contact structure is through the dielectric layer. A top surface of the S/D contact structure is aligned with a top surface of the mask layer. The semiconductor structure includes a metal silicide layer between the epitaxial source/drain feature and the contact feature, and the S/D contact structure is surrounded by the first dielectric layer. An electrical conductivity of the metal silicide layer is between an electrical conductivity of the S/D structure and an electrical conductivity of the S/D contact structure.

In some embodiments, a semiconductor structure is provided. The semiconductor structure includes a plurality of nanostructures formed over a substrate, and a gate structure formed over the nanostructures. The semiconductor structure includes a mask layer formed on the gate structure, and a source/drain (S/D) structure formed adjacent to the gate structure. The semiconductor structure also includes a first dielectric layer disposed over the S/D structure. The semiconductor structure includes an S/D contact structure extending through the first dielectric layer, and the S/D contact structure is through the dielectric layer. The semiconductor structure includes a metal silicide layer between the S/D structure and the S/D contact structure. An electrical conductivity of the metal silicide layer is between an electrical conductivity of the S/D structure and an electrical conductivity of the S/D contact structure. The electrical conductivity of the S/D contact structure is greater than the electrical conductivity of the S/D structure. The semiconductor structure includes a conductive via formed on the S/D contact structure, and a portion of the conductive via is formed on a top surface of the mask layer.

In some embodiments, a method for manufacturing a semiconductor structure is provided. The method includes forming a gate structure over a plurality of nanostructures, and forming a source/drain (S/D) structure adjacent to the gate structure. The method includes forming a mask layer over the gate structure. The method includes forming a first dielectric layer over the mask layer. The method includes forming an S/D contact structure through the first dielectric layer, and removing a portion of the S/D contact structure and a portion of the first dielectric layer to expose the mask layer. The method includes forming a second dielectric layer over the S/D contact structure and the mask layer. The method includes forming a conductive via through the second dielectric layer, and a dielectric constant of the mask layer is greater than a dielectric constant of the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of nanostructures formed over a substrate;
a gate structure formed over the nanostructures;
a mask layer formed on the gate structure;
an source/drain (S/D) structure formed adjacent to the gate structure;
a first dielectric layer formed over the S/D structure;
an S/D contact structure extending through the first dielectric layer, wherein the S/D contact structure is through the first dielectric layer, wherein a top surface of the S/D contact structure is aligned with a top surface of the mask layer;
a metal silicide layer between the epitaxial source/drain feature and the contact feature, wherein the S/D contact structure is surrounded by the first dielectric layer, wherein an electrical conductivity of the metal silicide layer is between an electrical conductivity of the S/D structure and an electrical conductivity of the S/D contact structure.

2. The semiconductor structure as claimed in claim 1, wherein a dielectric constant of the mask layer is greater than a dielectric constant of the first dielectric layer.

3. The semiconductor structure as claimed in claim 1, further comprising:
a second dielectric layer over the mask layer and the S/D contact structure; and
a conductive via formed through the second dielectric layer, wherein the conductive via is separated from the gate structure by the mask layer.

4. The semiconductor structure as claimed in claim 3, wherein a dielectric constant of the mask layer is greater than a dielectric constant of the second dielectric layer.

5. The semiconductor structure as claimed in claim 3, wherein the conductive via has an extending portion formed on a sidewall surface of the S/D contact structure.

6. The semiconductor structure as claimed in claim 3, wherein the conductive via passes through the second dielectric layer without passing through an etch stop layer.

7. The semiconductor structure as claimed in claim 1, further comprising:
an inner spacer layer between the gate structure and the S/D structure, wherein a sidewall surface of the inner spacer layer is aligned with a sidewall surface of the mask layer.

8. The semiconductor structure as claimed in claim 1, further comprising:
a gate spacer layer formed on a sidewall surface of the gate structure, wherein a dielectric constant of the first dielectric layer is greater than a dielectric constant of the gate spacer layer.

9. The semiconductor structure as claimed in claim 8, wherein a sidewall surface of the gate space layer is aligned with a sidewall surface of the mask layer.

10. A semiconductor structure, comprising:
a plurality of nanostructures formed over a substrate;
a gate structure formed over the nanostructures;
a mask layer formed on the gate structure;
an source/drain (S/D) structure formed adjacent to the gate structure;
a first dielectric layer disposed over the S/D structure;
an S/D contact structure extending through the first dielectric layer, wherein the S/D contact structure is through the first dielectric layer,
a metal silicide layer between the S/D structure and the S/D contact structure, wherein an electrical conductivity of the metal silicide layer is between an electrical conductivity of the S/D structure and an electrical conductivity of the S/D contact structure, wherein the electrical conductivity of the S/D contact structure is greater than the electrical conductivity of the S/D structure; and
a conductive via formed on the S/D contact structure, wherein a portion of the conductive via is formed on a top surface of the mask layer.

11. The semiconductor structure as claimed in claim 10, wherein a width of the conductive via is greater than a width of the S/D contact structure.

12. The semiconductor structure as claimed in claim 10, wherein the conductive via is through a second dielectric layer, not through an etch stop layer.

13. The semiconductor structure as claimed in claim 10, wherein an interface between the conducive via and the S/D contact structure is aligned with a top surface of the mask layer.

14. The semiconductor structure as claimed in claim 10, wherein the conductive via has an extending portion formed on a sidewall surface of the S/D contact structure.

15. The semiconductor structure as claimed in claim 10, further comprising:
a gate spacer layer formed on a sidewall surface of the gate structure, wherein a sidewall surface of the gate space layer is aligned with a sidewall surface of the mask layer.

16. The semiconductor structure as claimed in claim 10, wherein a bottom surface of the conductive via faces a top surface of the mask layer.

17. A method for manufacturing a semiconductor structure, comprising:
forming a gate structure over a plurality of nanostructures;
forming a source/drain (S/D) structure adjacent to the gate structure;
forming a mask layer over the gate structure;
forming a first dielectric layer over the mask layer;
forming a S/D contact structure through the first dielectric layer;
removing a portion of the S/D contact structure and a portion of the first dielectric layer to expose the mask layer;
forming a second dielectric layer over the S/D contact structure and the mask layer; and
forming a conductive via through the second dielectric layer, wherein a dielectric constant of the mask layer is greater than a dielectric constant of the second dielectric layer.

18. The method for manufacturing the semiconductor structure as claimed in claim 17, wherein a bottom surface of the conductive via faces a top surface of the mask layer.

19. The method for manufacturing the semiconductor structure as claimed in claim 17, further comprising:
forming a gate spacer layer on a sidewall surface of the gate structure, wherein a sidewall surface of the gate spacer layer is aligned with a sidewall surface of the mask layer.

20. The method for manufacturing the semiconductor structure as claimed in claim 17, wherein forming the S/D contact structure through the first dielectric layer further comprises:
forming a trench in the first dielectric layer;
forming a conducive material in the trench; and
forming a third dielectric layer on a sidewall surface of the conductive material to surround the conductive material.
